(19) United States
(12) Patent Application Publication
(10) Pub. No.: US 2014/0342236 A1
(43) Pub. Date: Nov. 20, 2014

(54) SCALABLE FABRICATION OF ONE-DIMENSIONAL AND THREE-DIMENSIONAL, CONDUCTING, NANOSTRUCTURED TEMPLATES FOR DIVERSE APPLICATIONS SUCH AS BATTERY ELECTRODES FOR NEXT GENERATION BATTERIES

(71) Applicant: UT-Battelle, LLC, Oak Ridge, TN (US)

(72) Inventor: Amit GOYAL, Knoxville, TN (US)

(21) Appl. No.: 14/448,625

(22) Filed: Jul. 31, 2014

Related U.S. Application Data
(63) Continuation-in-part of application No. 12/849,970, filed on Aug. 4, 2010.
Application No. 12/849,970 is a continuation-in-part of application No. 12/711,309, filed on Feb. 24, 2010, now Pat. No. 8,518,526.
(60) Provisional application No. 61/231,501, filed on Aug. 5, 2009.
(60) Provisional application No. 61/231,063, filed on Aug. 4, 2009.

(51) Int. Cl. H01M 4/78; H01M 4/04

(52) U.S. Cl. CPC H01M 4/78; H01M 4/0402
USPC 429/245; 429/209; 427/123

(57) ABSTRACT

Articles including an array of one-dimensional or three-dimensional nanopillar arrays disposed on a substrate and methods for the formation thereof. The methods can include filling a plurality of hollow nanopillars, which are supported on a substrate, with a first conductive material and removing the plurality of hollow nanopillars to leave a plurality of vertically-aligned, epitaxial nanopillars, comprising the first conductive material, on the substrate.

### CROSS-REFERENCES TO RELATED APPLICATIONS

This application is a Continuation-in-Part of U.S. patent application Ser. No. 12/849,970, filed Aug. 4, 2010, titled Vertically-Aligned Nanopillar Array on Flexible, Biaxially-Textured Substrates for Nanoelectronics and Energy Conversion Applications, which claimed priority to U.S. Provisional Application No. 61/231,501, filed Aug. 5, 2009, claimed priority to U.S. Provisional Application No. 61/231,063, filed Aug. 4, 2009, and was a continuation-in-part of U.S. application Ser. No. 12/711,309, entitled “Structures with Three Dimensional Nanofences Comprising Single Crystal Segments,” filed Feb. 24, 2010, the entireties of which are incorporated herein by reference.

### STATEMENT REGARDING FEDERALLY SPONSORED RESEARCH OR DEVELOPMENT

The United States Government has rights in this invention pursuant to contract no. DE-AC05-00OR22725 between the United States Department of Energy and UT-Battelle, LLC.

### BACKGROUND OF THE INVENTION

1. Field of the Invention

The invention relates generally to ordered, nanoarrays, and more specifically to ordered, one-dimensional and three-dimensional nanoarrays comprising conductive materials, and more specifically for use as battery electrodes.

2. Description of the Related Art

Ordered one-dimensional (1) and three-dimensional (3D) nanoarrays are required for advanced solar cell concepts and battery architectures among other applications. A scalable method is needed to achieve ordered 1D and 3D nanoarrays. Some applications would also benefit if the 1D and 3D nanoarray array included nanorods that were single-crystal in nature. Other applications would benefit if all of the nanorods that make up the nanoarray had the same orientation.

While fabrication of a variety of interesting nanostructures has been demonstrated in small samples, a predominant number of the methods for making such nanostructures are not readily scalable or completely reproducible. In many cases, for example, deposits in a furnace downstream trap have to be scraped and nanostructures harvested therefrom. Therefore, such nanostructures are prohibitively expensive and the utility thereof cannot be realized. Reproducible and controlled fabrication of nanostructures is needed for many novel electronic and electromagnetic devices such as those involving semiconductors and superconductors.

### BRIEF SUMMARY OF THE INVENTION

Various embodiments relate to an article having a substrate surface, such as a biaxially-textured substrate surface and a plurality of vertically-aligned, epitaxial nanopillars supported on the surface substrate. The nanopillars can include a coating layer or layers which can be electronically active.

According to certain embodiments, arrays of ordered, regularly-placed, 1D nanorods of metals/alloys can be formed by a scalable method. The 1D nanorods can be single-crystal-like when formed on a biaxially-textured substrate. Various embodiments meet the need for ordered one dimensional nanoarrays for applications such as advanced solar cell, battery architectures, electronic devices, and other applications. Various embodiments provide a scalable method for producing ordered 1D nanoarrays. Various embodiments provide a 1D nanoarray array including nanorads that are single-crystal in nature. Still other embodiments provide nanoarrays wherein all of the nanorods that make up the nanoarray have the same orientation.

Various embodiments relate to an article, particularly a battery electrode, that includes a biaxially-textured substrate and a plurality of vertically-aligned nanopillars disposed on a surface of the substrate. The biaxially-textured substrate can include a first conductive material. The plurality of nanopillars can include a second conductive material. The first conductive material can be selected from the group consisting of copper, nickel, aluminum, iron, silver and their alloys thereof, and combinations thereof. The plurality of nanopillars can be epitaxial. One or more of the plurality of nanopillars can be biaxially textured. One or more of the plurality of nanopillars can be {100}<100>. One or more of the plurality of nanopillars can be self-assembled with regular nanoscale spacings. One or more of the plurality of nanopillars can have a diameter in the range of 1-200 nm. The second conductive material can be selected from the group consisting of copper, nickel, aluminum, iron, silver and their alloys thereof, and combinations thereof. The surface of the substrate can be biaxially textured. The surface of the substrate can be {100}<100>.

According to various embodiments, the article, particularly the battery electrode, can further include a plurality of nanobranches supported by the nanopillars. The plurality of nanobranches can be horizontally-aligned, epitaxial, and can include a third conductive material. The nanobranches can be epitaxial with respect to the nanopillars upon which they are supported, for example. The third conductive material can be selected from the group consisting of copper, nickel, aluminum, iron, silver and their alloys thereof, and combinations thereof. One or more of the plurality of nanobranches can have a diameter in the range of 1-200 nm. One or more of the plurality of nanobranches can be single-crystal-like. One or more of the plurality of nanobranches can be cube-textured. One or more of the plurality of nanobranches can be self-assembled with regular nanoscale spacings.

Various embodiments relate to a method of making an article, particularly a battery electrode. The method can include providing a substrate that comprises a first metallic material; depositing a first layer of a metallic material onto the substrate; anodically oxidizing the first layer to form a first self-assembled nanostructure defining a first plurality of nano-hole columns; filling the first plurality of nano-hole columns with a third metallic material to form a first plurality of nanopillars; and removing the first self-assembled nanostructure to leave the first plurality of nanopillars supported on the surface of the substrate. Removing the first self-assembled nanostructure can include one selected from chemical etching, plasma etching, reverse sputtering, ion-bombardment, and combinations thereof. The surface of the substrate can be biaxially-textured, or cube-textured. The method can further include immersing the first plurality of nanopillars in an electrode material. The electrode material can be, for example, silicon. According to some particularly preferred embodiments, the first metallic material is copper or an alloy thereof. The first metallic material can be single-crystal-like. The second metallic material can be a metal that upon anodization forms an ordered array of nanohole columns through the first layer. According to some particularly preferred embodiments, the second metallic material is selected from aluminum and titanium. According to some particularly preferred embodiments, the third metallic material is copper or an alloy thereof. The third metallic material can be single-crystal-like. The third metallic material can be electrodeposited to fill the first plurality of hollow nanopillars. The first plurality of nano-hole columns can be arranged in a hexagonal, self-assembled pattern. The first plurality of nano-hole columns be defined by and/or can comprise alumina, which can be formed upon the anodization of the first layer, for example. Each of the first plurality of nano-hole columns can have a length of from 1 nm to 1 mm and a diameter of 1 nm to 100 nm. The first plurality of nanopillars can be vertically-aligned with respect to the surface of the substrate. The first plurality of nanopillars can be epitaxial with respect to the surface of the substrate.

According to various embodiments, the method of making an article, particularly a battery electrode, can further include depositing a resist layer on the substrate at interstices between the first plurality of nanopillars; depositing a second layer comprising a fourth metallic material on the resist and the first plurality of nanopillars; anodically oxidizing the second layer to form a second self-assembled nanostructure comprised of a second plurality of nano-hole columns, wherein the second plurality of nano-hole columns are perpendicular to the first plurality of nanopillars; filling the second plurality of nano-hole columns with a fifth metallic material to form a second plurality of nanopillars; and removing the second self-assembled nanostructure to leave the second plurality of nanopillars supported by the first plurality of nanopillars. Removing the second self-assembled nanostructure can include one selected from chemical etching, plasma etching, reverse sputtering, ion-bombardment, and combinations thereof. The second plurality of nanopillars can interconnect with the first plurality of nanopillars to form a nanofence. The method can further include immersing the first plurality of nanopillars in an electrode material. The electrode material can be, for example, silicon. The fourth metallic material can be aluminum. The fifth metallic material can be copper or an alloy thereof. The second self-assembled nanostructure can include alumina. The second plurality nano-hole columns can be arranged in a hexagonal, self-assembled pattern. The fifth metallic material can be electrodeposited to fill the second plurality of hollow nanopillars. The second plurality of nanopillars can be horizontally-aligned with respect to the surface of the substrate. The second plurality of nanopillars can be epitaxial. The resist layer can have a thickness of from a 1 nm to 100 nm.

### BRIEF DESCRIPTION OF THE DRAWINGS

These and other features, aspects, and advantages of the present invention will become better understood with reference to the following description and appended claims, and accompanying drawings where:

FIG. 1: is a side view of an article disclosed herein, having a plurality of nanopillars deposited on a support;

FIGS. 2A and 2B: are a top view and side view, respectively, of a nanorod deposited on a support;

FIGS. 3A and 3B: are a top view and side view, respectively, of a nanotube deposited on a support;

FIG. 4: is a cross-sectional view of an article disclosed herein, having a plurality of nanopillars immersed in a matrix phase;

FIGS. 5A and 5B: are a side view and top view, respectively, of an article disclosed herein, having an upper surface with interfaces between the nanopillars and the matrix phase;

FIGS. 6A and 6B: are a cross-sectional view and top view, respectively, of support supporting a nanorod having a coating deposited thereon;

FIG. 7A-H: is a sequence of side views showing the method of making a variety of articles disclosed herein with a plurality of nanotubes deposited on a support;

FIG. 8: is a side view of an article disclosed herein, having nanopillars comprising a plurality of stacked sub-pillars;

FIG. 9: is a side view of an article disclosed herein, having nanopillars comprising a plurality of stacked sub-pillars with a coating thereon and a matrix phase deposited between the nanopillars;

FIG. 10: is a side view of an article disclosed herein, having nanopillars comprising a plurality of stacked sub-pillars with sub-coatings deposited thereon and a matrix phase deposited between the nanopillars;

FIG. 11A-F: is a sequence of side views showing the method of making a variety of articles disclosed herein with a plurality of nanorods deposited on a support;

FIG. 12: is a photomicrograph showing the structure of an anodized aluminum oxide (AAO) template that is useful in carrying out examples of the present invention;

FIG. 13: is an image of MgO+Ni nanorods with branches grown on a MgO single crystal substrate;

FIG. 14A-14E: are schematic illustrations of various stages of a scalable method to form one-dimensional (1D) nanopillars;

FIG. 14F-14O: are schematic illustrations of various stages of a scalable method to form three-dimensional (3D) nanofences;

FIG. 15A-15D: are schematic illustrations of 1D nanopillars and three-dimensional (3D) nanofences immersed in an electrode material; and

FIG. 16: is a schematic illustration of a reel-to-reel configuration.

It should be understood that the various embodiments are not limited to the arrangements and instrumentality shown in the drawings.

### DETAILED DESCRIPTION OF THE INVENTION

The present invention may be understood more readily by reference to the following detailed description of preferred embodiments of the invention as well as to the examples included therein. All numeric values are herein assumed to be modified by the term “about,” whether or not explicitly indicated. The term “about” generally refers to a range of numbers that one of skill in the art would consider equivalent to the recited value (i.e., having the same function or result). In many instances, the term “about” may include numbers that are rounded to the nearest significant figure.

As used herein, a first layer is “supported on” second layer if the first layer is above the second layer in a stack, whereas a first layer is “deposited on” a second layer if the first layer is above and in direct contact with the second layer. In other words, there can be intermediate layers between a first layer supported on a second layer, whereas there are no intermediate layers if the first layer is deposited on the second layer. It is intended that where the phrase “supported on” is used in the specification, the layer can be either supported on or deposited on the layer by which it is supported.

As used herein, “epitaxy” refers to the deposition of a crystalline overlayer on a substrate, where there is registry between the overlayer and the substrate. The overlayer is called an “epitaxial” film or “epitaxial” layer. Epitaxial films may be grown from gaseous or liquid precursors. Because the substrate acts as a seed crystal, the deposited film may lock into one or more crystallographic orientations with respect to the substrate crystal. If the overlayer either forms a random orientation with respect to the substrate or does not form an ordered overlayer, it is termed non-epitaxial growth. If an epitaxial film is deposited on a substrate of the same composition, the process is called homoepitaxy; otherwise it is called heteroepitaxy. Homoepitaxy is a kind of epitaxy performed with only one material, in which a crystalline film is grown on a substrate or film of the same material. Heteroepitaxy is a kind of epitaxy performed with materials that are different from each other. In heteroepitaxy, a crystalline film grows on a crystalline substrate or film of a different material. Heterotopotaxy is a process similar to heteroepitaxy except that thin film growth is not limited to two-dimensional growth; the substrate is similar only in structure to the thin-film material.

As used herein, “non-epitaxial” refers to the deposition of a overlayer on a substrate, wherein there is no registry between the overlayer and the substrate.

As used herein, “registry” between an overlayer and a substrate means that there is a crystallographic orientational relationship between the atoms in the substrate and the overlayer.

Atomic arrangements in crystalline solids can be described by referring the atoms to the points of intersection of a network of lines in three dimensions. Such a network is called a “space lattice” and can be described as an infinite three-dimensional array of points. In crystallography, the terms crystal system, crystal family, and lattice system each refer to one of several classes of space groups, lattices, point groups, or crystals.

A lattice system is a class of lattices with the same point group. In three dimensions there are seven lattice systems: triclinic, monoclinic, orthorhombic, tetragonal, rhombohedral, hexagonal, and cubic. The lattice system of a crystal or space group is determined by its lattice but not always by its point group.

Crystal systems are a modification of the lattice systems to make them compatible with the classification according to point groups. They differ from crystal families in that the hexagonal crystal family is split into two subsets, called the trigonal and hexagonal crystal systems. Two point groups are placed in the same crystal system if the sets of possible lattice systems of their space groups are the same. A cubic crystal system comprises three equal axes at right angles and includes three space lattices: simple cubic, body-centered cubic, and face-centered cubic. A tetragonal crystal system comprises three axes at right angles, two of which are equal and includes two space lattices: simple tetragonal and body-centered tetragonal. An orthorhombic crystal system comprises three unequal axes at right angles and includes four space lattices: simple orthorhombic, body-centered orthorhombic, base-centered orthorhombic, and face-centered orthorhombic. A rhombohedral crystal system comprises three equal axes, equally inclined and includes one space lattice: simple rhombohedral. A hexagonal crystal system comprises two equal axes at 120 degrees and a third axis at right angles and includes one space lattice: simple hexagonal. A monoclinic crystal system comprises three unequal axes where one pair are not at right angles and includes two space lattices: simple monoclinic and base-centered monoclinic. A triclinic crystal system comprises three unequal axes that are unequally inclined and not at right angles, and includes one space lattice: simple triclinic.

A crystal family comprises point groups and is formed by combining crystal systems whenever two crystal systems have space groups with the same lattice. In three dimensions a crystal family is almost the same as a crystal system (or lattice system), except that the hexagonal and trigonal crystal systems are combined into one hexagonal family. In three dimensions there are six crystal families: triclinic, monoclinic, orthorhombic, tetragonal, hexagonal, and cubic. The crystal family of a crystal or space group is determined by either its point group or its lattice, and crystal families are the smallest collections of point groups with this property.

As used herein, “crystallographic orientation” refers to the particular crystal system to which a material belongs.

As used herein, “flexible” means capable of bending easily without breaking.

As used herein, “biaxially-textured” refers to two crystallographic axes being aligned. For example, the term “biaxially-textured” can refer to the {100}<100> crystallographic orientation in a substrate, which means that the (100) plane is aligned parallel to the flat plane of the substrate and the [100] direction is aligned along the long axis of the substrate or the rolling direction of the substrate. The degree of biaxial texture in a biaxially-textured surface, as specified by the FWHM of the out-of-plane and in-plane diffraction peak, can be within a range having a lower limit and/or an upper limit. The range can include or exclude the lower limit and/or the upper limit. The lower limit and/or upper limit can be selected from 0, 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, 3, 3.1, 3.2, 3.3, 3.4, 3.5, 3.6, 3.7, 3.8, 3.9, 4, 4.1, 4.2, 4.3, 4.4, 4.5, 4.6, 4.7, 4.8, 4.9, 5, 5.1, 5.2, 5.3, 5.4, 5.5, 5.6, 5.7, 5.8, 5.9, 6, 6.1, 6.2, 6.3, 6.4, 6.5, 6.6, 6.7, 6.8, 6.9, 7, 7.1, 7.2, 7.3, 7.4, 7.5, 7.6, 7.7, 7.8, 7.9, 8, 8.1, 8.2, 8.3, 8.4, 8.5, 8.6, 8.7, 8.8, 8.9, 9, 9.1, 9.2, 9.3, 9.4, 9.5, 9.6, 9.7, 9.8, 9.9, 10, 10.1, 10.2, 10.3, 10.4, 10.5, 10.6, 10.7, 10.8, 10.9, 11, 11.1, 11.2, 11.3, 11.4, 11.5, 11.6, 11.7, 11.8, 11.9, 12, 12.1, 12.2, 12.3, 12.4, 12.5, 12.6, 12.7, 12.8, 12.9, 13, 13.1, 13.2, 13.3, 13.4, 13.5, 13.6, 13.7, 13.8, 13.9, 14, 14.1, 14.2, 14.3, 14.4, 14.5, 14.6, 14.7, 14.8, 14.9, 15, 15.1, 15.2, 15.3, 15.4, 15.5, 15.6, 15.7, 15.8, 15.9, 16, 16.1, 16.2, 16.3, 16.4, 16.5, 16.6, 16.7, 16.8, 16.9, 17, 17.1, 17.2, 17.3, 17.4, 17.5, 17.6, 17.7, 17.8, 17.9, 18, 18.1, 18.2, 18.3, 18.4, 18.5, 18.6, 18.7, 18.8, 18.9, 19, 19.1, 19.2, 19.3, 19.4, 19.5, 19.6, 19.7, 19.8, 19.9, and 20 degrees. For example, according to certain preferred embodiments, the degree of biaxial texture in a biaxially-textured surface, as specified by the FWHM of the out-of-plane and in-plane diffraction peak, can be greater than 2 degrees and less than 20 degrees, preferably less than 15 degrees, and optimally less than 10 degrees. As will be understood the composition of the materials described herein can vary greatly depending on the particular application. The biaxially-textured surface can be the surface of any biaxially textured substrate including one or more layers. Examples of suitable materials for the substrate include, but are not limited to, a single crystal substrate; a biaxially textured substrate; and an untextured substrate having adhered thereon a biaxially-textured crystallographic surface, such as an ion-beam assisted deposition (IBAD) substrate.

As used herein, “vertically-aligned” features are aligned substantially normal to a surface. Vertically-aligned features can deviate from normal with respect to a surface by an angle within a range having a lower limit and/or an upper limit. The range can include or exclude the lower limit and/or the upper limit. The lower limit and/or upper limit can be selected from 0, 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, 3, 3.1, 3.2, 3.3, 3.4, 3.5, 3.6, 3.7, 3.8, 3.9, 4, 4.1, 4.2, 4.3, 4.4, 4.5, 4.6, 4.7, 4.8, 4.9, 5, 5.1, 5.2, 5.3, 5.4, 5.5, 5.6, 5.7, 5.8, 5.9, 6, 6.1, 6.2, 6.3, 6.4, 6.5, 6.6, 6.7, 6.8, 6.9, 7, 7.1, 7.2, 7.3, 7.4, 7.5, 7.6, 7.7, 7.8, 7.9, 8, 8.1, 8.2, 8.3, 8.4, 8.5, 8.6, 8.7, 8.8, 8.9, 9, 9.1, 9.2, 9.3, 9.4, 9.5, 9.6, 9.7, 9.8, 9.9, 10, 10.1, 10.2, 10.3, 10.4, 10.5, 10.6, 10.7, 10.8, 10.9, 11, 11.1, 11.2, 11.3, 11.4, 11.5, 11.6, 11.7, 11.8, 11.9, 12, 12.1, 12.2, 12.3, 12.4, 12.5, 12.6, 12.7, 12.8, 12.9, 13, 13.1, 13.2, 13.3, 13.4, 13.5, 13.6, 13.7, 13.8, 13.9, 14, 14.1, 14.2, 14.3, 14.4, 14.5, 14.6, 14.7, 14.8, 14.9, and 15 degrees. For example, according to certain preferred embodiments, vertically-aligned features can deviate from normal with respect to a surface by an angle of less than 15 degrees, or less than 10 degrees, or less than 5 degrees, or less than 1 degree, or less than 0.1 degrees.

As used herein, “horizontally-aligned” features are aligned substantially parallel to a surface. Vertically-aligned features can deviate from parallel with respect to a surface by an angle within a range having a lower limit and/or an upper limit. The range can include or exclude the lower limit and/or the upper limit. The lower limit and/or upper limit can be selected from 0, 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, 3, 3.1, 3.2, 3.3, 3.4, 3.5, 3.6, 3.7, 3.8, 3.9, 4, 4.1, 4.2, 4.3, 4.4, 4.5, 4.6, 4.7, 4.8, 4.9, 5, 5.1, 5.2, 5.3, 5.4, 5.5, 5.6, 5.7, 5.8, 5.9, 6, 6.1, 6.2, 6.3, 6.4, 6.5, 6.6, 6.7, 6.8, 6.9, 7, 7.1, 7.2, 7.3, 7.4, 7.5, 7.6, 7.7, 7.8, 7.9, 8, 8.1, 8.2, 8.3, 8.4, 8.5, 8.6, 8.7, 8.8, 8.9, 9, 9.1, 9.2, 9.3, 9.4, 9.5, 9.6, 9.7, 9.8, 9.9, 10, 10.1, 10.2, 10.3, 10.4, 10.5, 10.6, 10.7, 10.8, 10.9, 11, 11.1, 11.2, 11.3, 11.4, 11.5, 11.6, 11.7, 11.8, 11.9, 12, 12.1, 12.2, 12.3, 12.4, 12.5, 12.6, 12.7, 12.8, 12.9, 13, 13.1, 13.2, 13.3, 13.4, 13.5, 13.6, 13.7, 13.8, 13.9, 14, 14.1, 14.2, 14.3, 14.4, 14.5, 14.6, 14.7, 14.8, 14.9, and 15 degrees. For example, according to certain preferred embodiments, horizontally-aligned features can deviate from parallel with respect to a surface by an angle of less than 15 degrees, or less than 10 degrees, or less than 5 degrees, or less than 1 degree, or less than 0.1 degrees. As used herein, “nanoscale” refers to a size measurable in nanometers or microns. The term “nanoscale” can include a size within a range having a lower limit and/or an upper limit. The range can include or exclude the lower limit and/or the upper limit. The lower limit and/or upper limit can be selected from 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 110, 120, 130, 140, 150, 160, 170, 180, 190, 200, 210, 220, 230, 240, 250, 260, 270, 280, 290, 300, 310, 320, 330, 340, 350, 360, 370, 380, 390, 400, 410, 420, 430, 440, 450, 460, 470, 480, 490, 500, 510, 520, 530, 540, 550, 560, 570, 580, 590, 600, 610, 620, 630, 640, 650, 660, 670, 680, 690, 700, 710, 720, 730, 740, 750, 760, 770, 780, 790, 800, 810, 820, 830, 840, 850, 860, 870, 880, 890, 900, 910, 920, 930, 940, 950, 960, 970, 980, 990, and 1000 nanometers. For example, according to certain preferred embodiments, the term “nanoscale” includes a size of from 1 to 100 nanometers.

As used herein, “nanopillar” refers to a substantially cylindrical column, rod, or tube having at least one nanoscale dimension. The at least one nanoscale dimension can be an outer diameter, an inner diameter (in the case of a tube), and/or a length as measured from a substrate upon which the nanopillar is deposited to an outer extremity of the nanopillar. The term “nanopillar” encompasses the terms “nanorod” and “nanotube.” The term “substantially cylindrical” means generally having the shape of a cylinder and includes objects and structures that deviate from the precise geometric concept of a cylinder. As used herein, “nanorod” refers to a solid nanopillar. A nanorod can be formed of formed of one or more compositions. For example, a nanorod can be formed of a single, uniform composition. As used herein, “nanotube” refers to a hollow nanopillar. A nanotube can be, but is not necessarily filled with a core phase. Nanopillars can have at least one dimension ranging from 1 to 500 nm, or 5 to 250 nm, or 10 to 100 nm, or any combination of these endpoints, e.g., 250 to 500 nm. Nanopillars generally have at least one dimension that is less than 100 nm. An outer diameter of the vertically-aligned, epitaxial nanopillars can range from 1 to 100 nm, or from 2 to 75 nm, or from 5 to 50 nm, or any combination of these endpoints, e.g., 2 to 50 nm. An inner diameter of nanotubes can range from 1 to 50 nm, or from 2 to 40 nm, or from 3 to 30 nm, or any combination of these endpoints, e.g., 2 to 3 nm. As used herein, “nanofence” refers to a three-dimensional, grid-like structure having interconnected branches extending in one or more directions.

As used herein, “array” refers to a systematic or random arrangement of objects, usually in rows and columns. For example, a nanopillar array comprises a plurality of nanopillars arranged in a systematic grouping, which can include one or more rows and/or one or more columns of nanopillars.

As used herein, “ordered array” refers to a systematic arrangement of objects, usually in rows and columns.

As used herein, “regular nanoscale spacings” can refer to distances between immediately adjacent nanopillars in a nanopillar array. Two nanopillars are immediately adjacent, if they are in the vicinity of each other and if no third nanopillar is positioned between them. The distances between immediately adjacent nanopillars can be on a nanoscale as defined herein. The distances are “regular” if the magnitude of each distance deviates from an average of all distances between immediately adjacent nanopillars by a percentage within a range having a lower limit and/or an upper limit. The range can include or exclude the lower limit and/or the upper limit. The lower limit and/or upper limit can be selected from 0, 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, 3, 3.1, 3.2, 3.3, 3.4, 3.5, 3.6, 3.7, 3.8, 3.9, 4, 4.1, 4.2, 4.3, 4.4, 4.5, 4.6, 4.7, 4.8, 4.9, 5, 5.1, 5.2, 5.3, 5.4, 5.5, 5.6, 5.7, 5.8, 5.9, 6, 6.1, 6.2, 6.3, 6.4, 6.5, 6.6, 6.7, 6.8, 6.9, 7, 7.1, 7.2, 7.3, 7.4, 7.5, 7.6, 7.7, 7.8, 7.9, 8, 8.1, 8.2, 8.3, 8.4, 8.5, 8.6, 8.7, 8.8, 8.9, 9, 9.1, 9.2, 9.3, 9.4, 9.5, 9.6, 9.7, 9.8, 9.9, 10, 10.1, 10.2, 10.3, 10.4, 10.5, 10.6, 10.7, 10.8, 10.9, 11, 11.1, 11.2, 11.3, 11.4, 11.5, 11.6, 11.7, 11.8, 11.9, 12, 12.1, 12.2, 12.3, 12.4, 12.5, 12.6, 12.7, 12.8, 12.9, 13, 13.1, 13.2, 13.3, 13.4, 13.5, 13.6, 13.7, 13.8, 13.9, 14, 14.1, 14.2, 14.3, 14.4, 14.5, 14.6, 14.7, 14.8, 14.9, and 15 percent. For example, according to certain preferred embodiments, the distances are “regular” if the magnitude of each distance deviates from an average of all distances between immediately adjacent nanopillars by a percentage within a range of from 0 to 10 percent.

As used herein, “nano-hole column” refers to a nanoscale void in a surface or layer. According to various embodiments, a plurality of nano-hole columns can be formed in a surface or layer via anodic oxidization. The plurality of nano-hole columns can form a self-assembled array or pattern of nanoscale holes or voids in the surface or layer. The plurality of nano-hole columns can have a regularly-occurring shape, such as, but not limited to a hexagonal shape.

As used herein, “sub-pillars” refers to a subpart of a nanopillar having a different composition than another sub-pillar forming part of the same nanopillar. In other words, a nanopillar includes subpillars, if it has segments with different compositions along its length. The sub-pillars can be stacked on one another. Nanopillars formed from sub-pillars can be used to replace any of the nanopillars described herein. For example, sub-pillar-based nanopillars can be coated; can be surrounded by a matrix phase, or both. In addition, each of the sub-pillars can be coated with a sub-coating and can be immersed by a matrix phase.

As used herein, “nanopattern” refers to a nanoscale arrangement of features. The arrangement can be ordered or random.

As used herein, “metallic” or “metallic material” refers to a composition including but not limited to aluminum, antimony, arsenic, barium, beryllium, bismuth, boron, cadmium, cesium, chromium, cobalt, copper, gallium, germanium, gold, hafnium, indium, iron, lead, lithium, manganese, mercury, molybdenum, nickel, platinum, palladium, rhodium, iridium, osmium, ruthenium, rhenium, rubidium, scandium, selenium, silver, strontium, tantalum, tellurium, thallium, thorium, tin, titanium, tungsten, vanadium, zinc, zirconium, alloys, and combinations thereof.

As used herein, “conductive” or “conductive material” refers to any conductive material, including but not limited to a metallic material.

As used herein, “photovoltaic material” refers to a material including but not limited to single-crystal silicon, polycrystalline silicon, gallium arsenide, amorphous silicon, cadmium telluride, copper indium diselenide, and combinations thereof.

As used herein, “electrical storage material” refers to a material including but not limited to graphene, and solar energy storage materials described in U.S. Pat. No. 4,497,724 which is hereby incorporated by reference in its entirety.

As used herein, “catalyst” refers to a substance that increases the rate of a chemical reaction without itself undergoing any permanent chemical change. As used herein, “nanocatalyst” refers to a nanoscale catalyst. A variety of nanocatalysts can be used in accordance with the various embodiments including various metallic materials.

As used herein, “nanocatalyst pattern” refers to an arrangement of nanocatalysts. The arrangement can be ordered or random.

As used herein, “anodization” is an electrolytic process used to form an oxide layer on the surface of metal parts.

As used herein, “anodization catalyst layer” refers to a layer deposited on a surface which will be subsequently anodized. The anodization catalyst layer can include a metallic material.

As used herein, “single-crystal” refers to a material in which the crystal lattice of the entire sample is continuous and unbroken to the edges of the sample, with no grain boundaries.

As used herein, “single-crystal-like” refers to a material which has an orientation almost like that of a single-crystal but is polycrystalline.

As used herein, “1D” or “one-dimensional” refers to nanopillars that extend predominantly in a single axial direction relative to a surface upon which they are deposited. One dimensional nanopillars have dimensions in three axial directions, but their predominant dimension is in a single direction, e.g. vertical.

As used herein, “3D” or “three-dimensional” refers to nanopillars that extend in three axial directions relative to a surface upon which they are deposited. A three-dimensional nanopillar can be branched.

As used herein, “branch” refers to a portion of a three-dimensional nanopillar extending along an axis that is substantially parallel to a surface upon which the nanopillar is deposited. As used herein, “branched” refers to nanopillar having one or more braches, e.g. a three-dimensional nanopillar. The branches of a three-dimensional nanopillar can be connected or unconnected. As used herein, “unbranched” refers to a nanopillar without branches.

As used herein, “resist” refers to a thin layer used to transfer a circuit pattern to the semiconductor substrate which it is deposited upon. A resist can be patterned via lithography to form a (sub)micrometer-scale, temporary mask that protects selected areas of the underlying substrate during subsequent processing steps. The material used to prepare said thin layer is typically a viscous solution. Resists are generally proprietary mixtures of a polymer or its precursor and other small molecules (e.g. photoacid generators) that have been specially formulated for a given lithography technology. Resists used during photolithography are called photoresists.

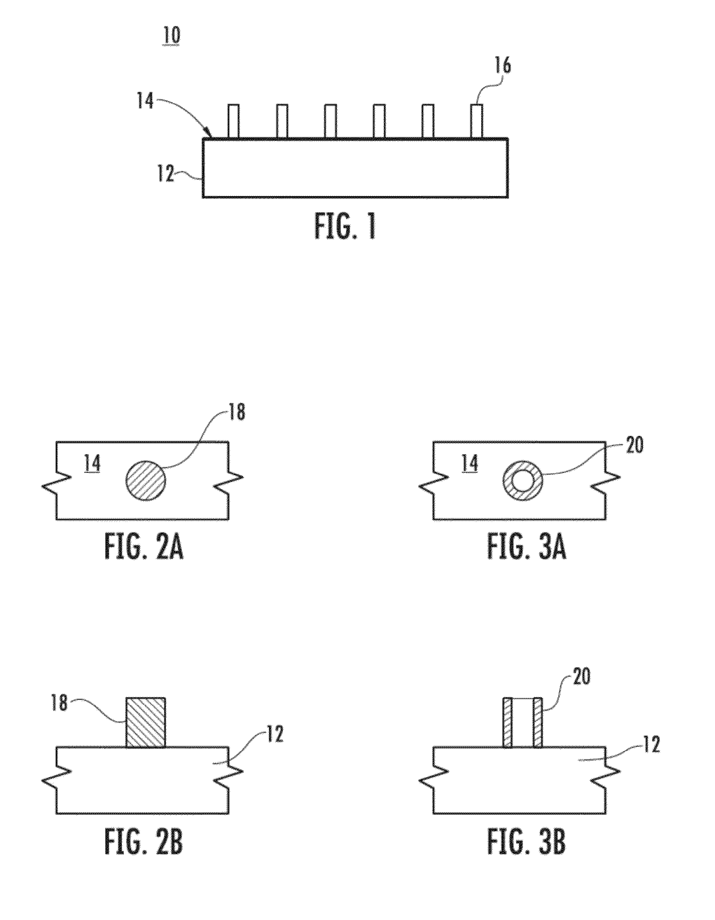

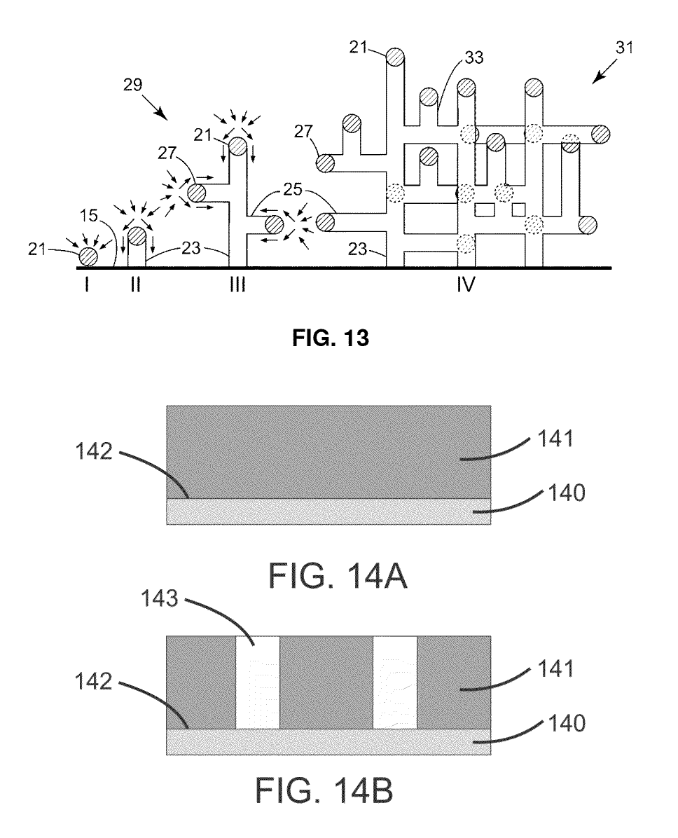

As shown in FIGS. 1-11, an article 10 can include a substrate 12. The substrate 12 can have a biaxially textured surface 14. The substrate 12 can be a metallic material or can include a metallic material. A plurality of nanopillars 16 can be supported on the substrate 12, particularly on the biaxially-textured surface 14. One or more of the plurality of nanopillars can be vertically-aligned. One or more of the plurality of nanopillars can be epitaxial with respect to the biaxially-textured surface 14. One or more of the plurality of nanopillars 16 can be single crystal or single-crystal-like nanopillars. The nanopillars 16 in any of the embodiments described herein can be branched or unbranched. As can be seen in FIG. 13, where the nanopillars are branched, the branches can extend from a first nanopillar to a second nanopillar.

FIG. 1 is a side view of an article 10, having a plurality of nanopillars 16 deposited on a substrate 12, having a biaxially-textured surface 14.

FIG. 2A is a top view and FIG. 2B is a side view of a nanopillar in the form of a nanorod 18 deposited on a biaxially-textured surface 14 of a substrate 12.

FIG. 3A is a top view and FIG. 3B is a side view of a nanopillar in the form of a nanotube 20 deposited on a biaxially-textured surface 140 of a substrate 12.

As shown in FIGS. 2A, 2B, 3A, and 3B, the plurality of nanopillars 16 can be nanorods 18, nanotubes 20, or combinations of both nanorods 18 and nanotubes 20.

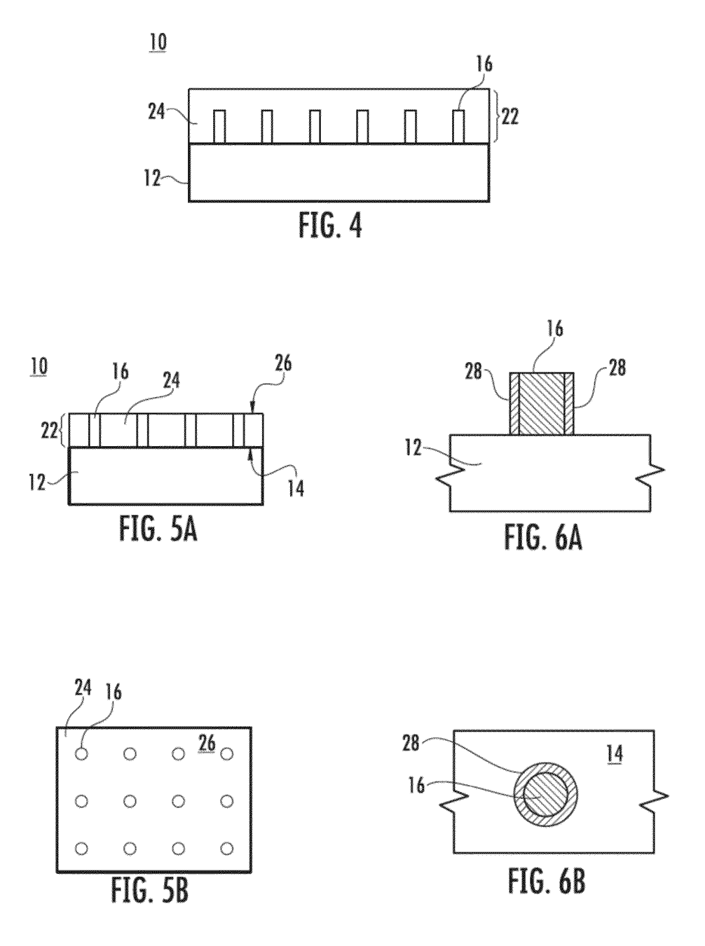

FIG. 4 is a cross-sectional view of an article 10, having a plurality of nanopillars 16 disposed on a substrate 12. The plurality of nanopillars 16 are immersed in a matrix phase 24 to form an electronically active layer 22 that includes the matrix phase 24 and the nanopillars 16. The plurality of nanopillars 16 can be vertically-aligned and epitaxial. The substrate 12 can include a biaxially-textured surface. As shown in FIG. 4, the matrix phase 24 completely immerses the plurality of nanopillars 16.

FIG. 5A is a side view and FIG. 5B is a top view of an article 10, having a plurality of nanopillars 16 disposed on a substrate 12. The plurality of nanopillars 16 are immersed in a matrix phase 24 to form an electronically active layer 22 that includes the matrix phase 24 and the nanopillars 16. The plurality of nanopillars 16 can be vertically-aligned and epitaxial. The substrate 12 can include a biaxially-textured surface 14. As shown in FIG. 5A, the matrix phase 24 does not completely immerse the nanopillars 16. The nanopillars 16 and the matrix phase 24 can be coextensive along an upper surface 26 of the electronically active layer 22. In other words, the upper surface 26 can include interfaces between the nanopillars 16 and the matrix phase 24.

The matrix phase 24 can be continuous, while the vertically-aligned nanopillars can be spatially separated in an ordered array. The matrix phase 24 can be amorphous or crystalline depending on the particular function of the article 10 and the electronically active layer 22. The matrix phase 24 can be any material useful in an article 10 having a substrate 12 with a biaxially textured surface 14, including, but not limited to a photovoltaic material or an electrical storage material.

FIG. 6A is a cross-section view and FIG. 6B is a top view of a nanopillar 16 disposed on a substrate 12. The nanopillar 16 has a coating 28 disposed on its outer surface. Although only one nanopillar 16 is shown, the substrate 12 can include a plurality of nanopillars 16 coated with a coating 28. The nanopillar(s) 16 can be epitaxial with respect to the substrate 12. The plurality of nanopillars 16 can be vertically-aligned on the substrate 12. The coating 28 can be an epitaxial layer deposited on the nanopillar(s) 16.

The nanopillar(s) 16 coated with the coating 28 can optionally be immersed in a matrix phase 24, as shown in any of FIG. 4, FIG. 5A, and FIG. 5B.

The coating 28 can have a first composition and the matrix phase 24 can have a second composition. The first and second compositions can be the same or different.

The coating 28 can have a first crystallographic orientation and the matrix phase 24 can have a second crystallographic orientation. The first and second crystallographic orientations can be the same or different. The first crystallographic orientation can be the same as the crystallographic orientation of the nanopillars 16 and the second crystallographic orientation can be the same as that of the biaxially-textured surface 14. The {100] orientation, being particularly preferred.

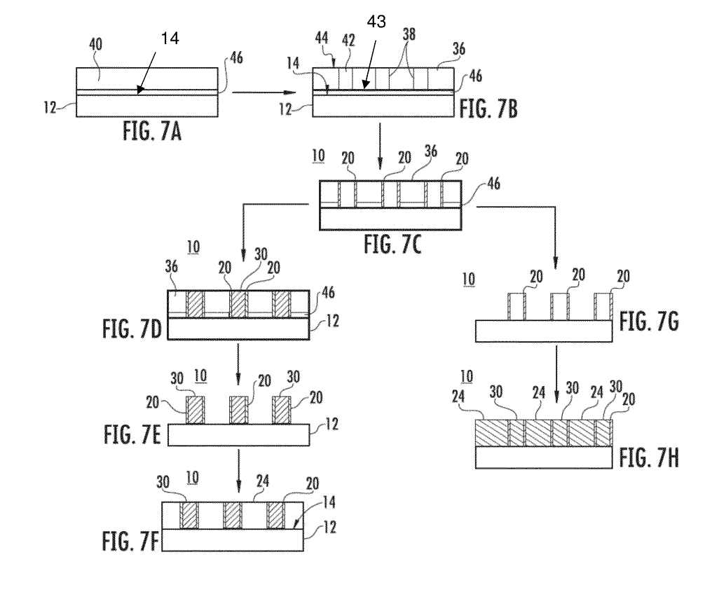

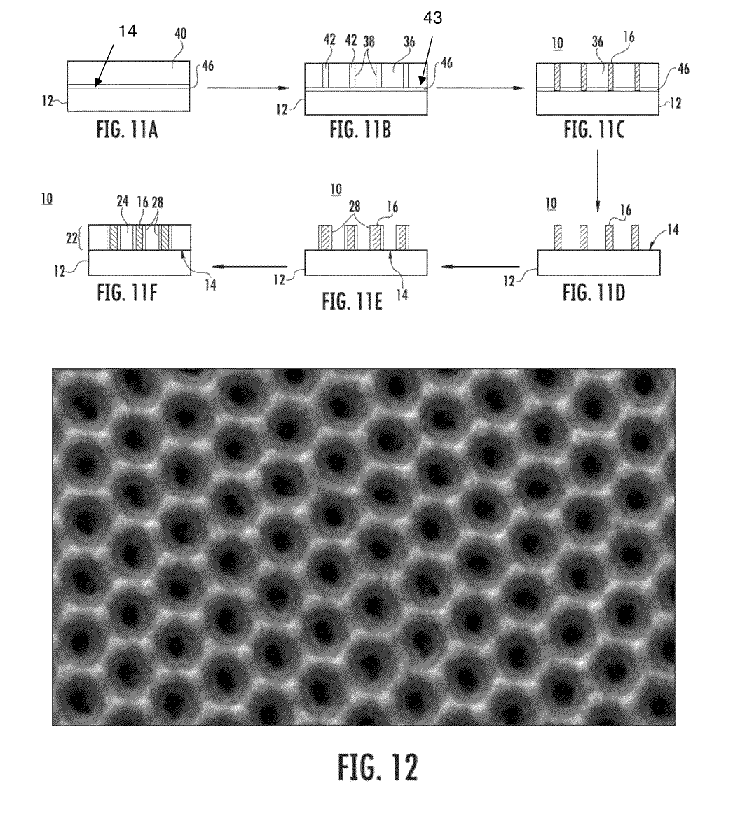

FIGS. 7A-H show a sequence of side views illustrating a method of making articles 10, according to various embodiments, having a plurality of nanopillars 16 deposited on a support 12. The nanopillars 16 can be nanotubes 20. It is noted that a similar method can be used to produce nanorods 18, as shown in FIG. 11C.

Referring to FIG. 7A, the method can include providing a substrate 12 having a biaxially-textured surface 14. According to some embodiments, the substrate 12 can include a layer having a biaxially-textured surface. Exemplary techniques for producing a biaxially-textured surfaces include RABiTS (Rolling-assisted biaxially-textured substrates) and IBAD (Ion-beam assisted substrates), which enable reproducible fabrication of wide-area, long length, single-crystal-like and single-crystal substrates. See, for example, U.S. Pat. No. 7,087,113 by Goyal, which is hereby incorporated by reference in its entirety. Additional exemplary techniques for producing biaxially-textured substrates include, but are not limited to, inclined substrate deposition (ISD), ion-beam assisted deposition (IBAD) or single substrates by secondary recrystallization.

Still referring to FIG. 7A, an anodization catalyst layer 46 is deposited on the biaxially-textured surface 14 of the substrate 12. The anodization catalyst layer 46 is optional. In other words, the anodization catalyst layer 46 can be present or absent depending on the desired embodiment. The anodization catalyst layer can be a metallic material. According to certain particularly preferred embodiments, the anodization catalyst layer can be aluminum.

A template precursor layer 40 can be deposited on the anodization catalyst layer 46. In embodiments where the anodization catalyst layer 46 is not present, the precursor layer 40 can be deposited directly onto the biaxially-textured surface 14 of the substrate 12. According to other embodiments, the anodization catalyst layer 46 can be supported on the biaxially textured surface 14 and the template precursor layer 40 can be supported on the anodization catalyst layer 46. Exemplary materials for the template precursor layer 40 include metallic materials. According to certain preferred embodiments, the template precursor layer 40 can be copper, titanium, magnesium, zinc, niobium, tantalum, aluminum and alloys thereof. According to certain particularly preferred embodiments, the template precursor layer 40 can include copper and/or copper alloys.

Referring to FIG. 7B, the template precursor layer 40 can be anodized to form a template 36. The template 36 can define a nanocatalyst pattern 38. The nanocatalyst pattern 38 can include pores 42 formed during the anodizing step. The pores 42 can extend a distance from a top surface 44 of the template 36 to a bottom surface 43 of the template 36. The distance can be a fraction of the total depth of the template 36. The fraction can be within a range having a lower limit and/or an upper limit. The range can include or exclude the lower limit and/or the upper limit. The lower limit and/or upper limit can be selected from 0, 0.1, 0.2, 0.3, 0.4, 0.5, 0.6, 0.7, 0.8, 0.9, and 1. For example, according to certain preferred embodiments, the fraction can be from 0 to 1. If the pores extend from the top surface 44 to the bottom surface 43, the fraction is 1, and this generally requires complete anodization of the metal in the template precursor layer 40.

Referring to FIG. 7C, after producing the template 36, a plurality of nanotubes 20 can be grown on the biaxially-textured surface 14 at the locations where the catalyst layer 46 or the biaxially-textured surface 14 is present. In other words, the metal catalyst can catalyze the growth of the nanorod where it is present. The nanotubes 20 can be vertically-aligned. The nanotubes 20 can be epitaxial with respect to the biaxially-textured surface 14 of the substrate 12.

In some instances, after formation of the template 36, debris may be left behind to cover the biaxially-textured surface 14 of the substrate 12. The debris can include, but is not limited to anodized or unanodized portions of the anodization catalyst layer 46, and/or anodized or unanodized portions of the template 36. In such instances, it may be necessary to remove the debris prior to growing the nanotubes 20. In addition to debris, films and layers can form during the process steps. One approach for removing such films, layers or debris, including using an etchant. The etchant can include one or more selected from one of many standard etchants including but not limited to copper(II) chloride, copper(II) sulfate, hydrochloric acid, nitric acid, hydrofluoric acid, potassium ferricyanide, potassium hydroxide, picric acid, and combinations thereof.

Referring to FIGS. 7D-H, once the nanotubes 20 are formed in the template 36 it is possible fill the core of the nanotubes 20 with a core phase 30 in a variety of ways. The core phase 30 can be epitaxial or non-epitaxial with respect to the biaxially-textured surface 14 of the substrate 12.

FIG. 7D shows the nanotubes 20 filled with a core phase 30 prior to removal of the template 36. The core phase 30 can be any material useful in an article 10 having a substrate 12 with a biaxially-textured surface 14, including, but not limited a metallic material, a photovoltaic material, an electrical storage material, and combinations thereof.

FIG. 7E shows that after the nanotubes 20 are filled with the core phase 30, the template 36 can be removed. The template 36 can be removed using an etchant that dissolves the template material 36, but not the substrate 12 or nanorods 18. The etching can continue until the exterior surface of the nanopillars 16 and the biaxial textured surface 14 are exposed. In instances where an anodization catalyst layer 46 is utilized, the catalyst layer 46 can also be removed at the time the template 36 is removed or in a separate step. The etchant can include one or more selected from a list of standard etchants including but not limited to copper(II) chloride, copper(II) sulfate, hydrochloric acid, nitric acid, hydrofluoric acid, potassium ferricyanide, potassium hydroxide, picric acid, and combinations thereof.

FIG. 7F, shows that matrix phase 24 can optionally be deposited around the nanotubes 20. The matrix phase 24 can be the different from or the same as the core phase 30.

FIGS. 7G and 7H show an alternative embodiment, in which the template 36 is removed prior to filling the nanotubes 20 with the core phase 30.

FIG. 7G shows that the template 36 can be removed to produce a plurality of nanotubes 20 deposited on the biaxially-textured substrate 14. The nanotubes 20 can be vertically-aligned. The nanotubes 20 can be epitaxial with respect to the biaxially-textured surface 14 of the substrate 12.

FIG. 7H shows that a matrix phase 24 can be deposited on the biaxially-textured surface 14 of the substrate 12. The core phase 30 can be co-deposited with the matrix phase 24. In this instance, the core phase 30 and matrix phase 24 will have the same composition.

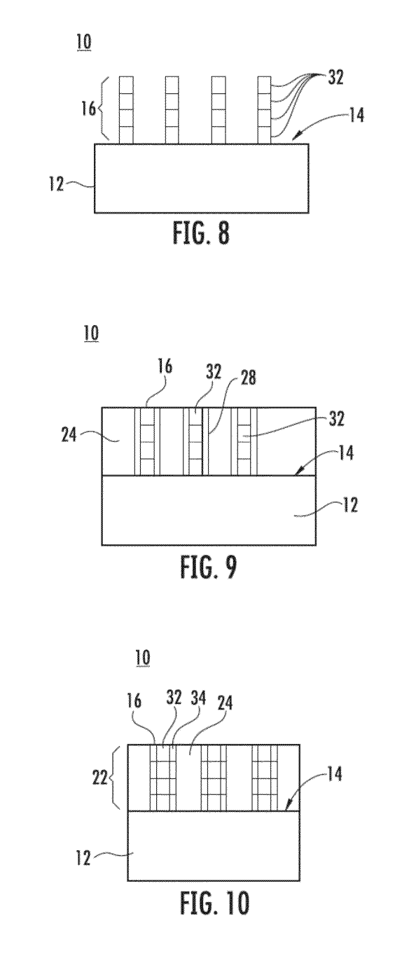

A method is also disclosed for producing nanopillars 16 that include a plurality of sub-pillars 32, as shown in FIGS. 8-10. The sub-pillars 32 can be nanorods 18, nanotubes 20, or both.

FIG. 8 is a side view of an article 10, having nanopillars 16 comprising a plurality of stacked sub-pillars 32 disposed on a biaxially-textured surface 14 of a substrate 12. The nanopillars 16 can be vertically-aligned. The nanopillars 16 can be epitaxial with respect to the substrate 12. The nanopillars 16 can include at least two epitaxial sub-pillars 32 having different compositions along a length of each nanopillar 16. Each of the sub-pillars 32 can have a composition and crystallographic orientation that is the same or different from the sub-pillar 32 on which it is deposited. The sub-pillars 32 can be stacked on one another.

FIG. 9 is a side view of an article 10, having nanopillars 16 comprising a plurality of stacked sub-pillars 32 with a coating 28 thereon and a matrix phase 24 deposited between the nanopillars 16. Nanopillars 16 formed from sub-pillars 32 can be used to replace any of the nanopillars 16 described herein. For example, sub-pillar-based nanopillars 16 can be coated; can be surrounded by a matrix phase 24, or both.

FIG. 10 is a side view of an article 10, having nanopillars 16 comprising a plurality of stacked sub-pillars 32 with sub-coatings 34 deposited thereon and a matrix phase 24 deposited between the nanopillars.

FIGS. 11A-F are a sequence of side views showing the method of making a variety of articles disclosed herein with a plurality of nanorods deposited on a support.

Referring to FIG. 11A, and as already described with respect to FIG. 7A, the method can include providing a substrate 12 having a biaxially-textured surface 14. According to some embodiments, the substrate 12 can include a layer having a biaxially-textured surface. An anodization catalyst layer 46 is deposited on the biaxially-textured surface 14 of the substrate 12. The anodization catalyst layer 46 is optional. In other words, the anodization catalyst layer 46 can be present or absent depending on the desired embodiment. A template precursor layer 40 can be deposited on the anodization catalyst layer 46. In embodiments where the anodization catalyst layer 46 is not present, the precursor layer 40 can be deposited directly onto the biaxially-textured surface 14 of the substrate 12. According to other embodiments, the anodization catalyst layer 46 can be supported on the biaxially textured surface 14 and the template precursor layer 40 can be supported on the anodization catalyst layer 46.

Referring to FIG. 11B, and as already described with respect to FIG. 7B, the template precursor layer 40 can be anodized to form a template 36. The template 36 can define a nanocatalyst pattern 38. The nanocatalyst pattern 38 can include pores 42 formed during the anodizing step.

Referring to FIG. 11C, after producing the template 36, a plurality of nanopillars 16 can be grown on the biaxially-textured surface 14. The nanopillars 16 can be vertically-aligned. The nanopillars can be nanorods. The nanopillars can be epitaxial with respect to the biaxially-textured surface 14 of the substrate 12.

Referring to FIG. 11D, the template 36 can be removed using an etchant that dissolves the template material 36, but not the substrate 12 or nanorods 18. The etching can continue until the exterior surface of the nanopillars 16 and the biaxial textured surface 14 are exposed. In instances where an anodization catalyst layer 46 is utilized, the catalyst layer 46 can also be removed at the time the template 36 is removed or in a separate step. The etchant can include one or more selected from copper(II) chloride, copper(II) sulfate, hydrochloric acid, nitric acid, hydrofluoric acid, potassium ferricyanide, potassium hydroxide, picric acid, and combinations thereof.

Referring to FIG. 11E, following removal of the template 36, an optional coating 28 can be deposited on the plurality of vertically-aligned, epitaxial nanopillars 16. The coating 28 can be epitaxial or non-epitaxial. The coating 28 can be applied using nanofilm deposition techniques know in the art.

Referring to FIG. 11F, the matrix phase 24 can be deposited on the biaxially textured surface 14. The matrix phase 24 can be disposed between the plurality of vertically-aligned, epitaxial nanopillars 16. In some examples, the plurality of vertically-aligned, epitaxial nanopillars 16 can be immersed in the matrix phase 24. Where the matrix phase 24 is epitaxial, the matrix phase can be grown or deposited around the nanopillars in two broadly defined ways:

(1) In-Situ Deposition: In this case, the film is deposited epitaxially on the biaxially textured surface 14 over, around and throughout the plurality of nanopillars 16 using an in-situ deposition technique including, but not limited to, laser ablation, sputtering, e-beam co-evaporation, chemical vapor deposition, metal-organic chemical vapor deposition, chemical solution deposition, liquid phase epitaxy, hybrid liquid phase epitaxy, and the like. The result is an epitaxial matrix phase 24 deposited on the biaxially textured surface 14 between the nanopillars 16.

(2) Ex-Situ Deposition: In this case, first a precursor film is deposited on the biaxially textured surface 14 over, around and throughout the plurality of nanopillars 16. This is followed by a heat-treatment or an annealing step at a temperature greater than 500° C. to form an epitaxial matrix phase 24, e.g., a superconductor matrix phase, within which the nanopillars 16 are embedded. Examples of techniques for this step include, but are not limited to, chemical solution deposition methods, such as using metal-organic deposition (MOD) techniques, particularly with fluorine-containing precursors or e-beam or thermal co-evaporation with fluorine-containing precursors.

With respect to any embodiment described herein, the matrix phase 24, nanopillars 16, coatings 28 and core phase 30 can be any material useful in an article 10 having a substrate 12 with a biaxially textured surface 14, including, but not limited to a metallic material, a photovoltaic material, an electrical storage material, and combinations thereof.

Exemplary compositions for the matrix phase 24, nanopillars 16, coatings 28 and core phase 30 include, but are not limited to, metallic materials, oxides, nitrides, borides, carbides and combinations thereof. Where the composition of the matrix phase 24, nanopillars 16, coatings 28 and/or core phase 30 is not amorphous, the compositions can have a variety of crystal structures, which independently include, but are not limited to, rock-salt, fluorite, perovskite, double-perovskite and pyrochlore. The nanopillars 16, coatings 28 and/or core phase 30 can be formed using any technique useful for applying thin films, whether epitaxial or not, including, but not limited to, laser ablation, sputtering, e-beam co-evaporation, chemical vapor deposition, metal-organic chemical vapor deposition, chemical solution deposition, liquid phase epitaxy, hybrid liquid phase epitaxy, chemical solution deposition methods, such as using metal-organic deposition (MOD) techniques, and the like. Of course, the composition and deposition technique of the matrix phase 24, nanopillars 16, coatings 28 and core phase 30, will depend on the particular application in which the article 10 is used.

FIG. 12 is a photomicrograph showing the structure of an anodized aluminum oxide (AAO) template that is useful in carrying out examples of the present invention. If the aluminum layer is non-epitaxial, the structure of the AAO template is shown in FIG. 12. In case the aluminum is deposited epitaxially on the top buffer layer of the substrate, then it will have a [100] orientation.

Anodic oxidation of an epitaxial Al layer may result in a pore structure which is different from that shown in FIG. 12. Regardless, anodic oxidation is performed until the surface of the cap or top buffer layer of the large-area single crystal substrate is visible through the nanopore structure. The surface of the cap layer inside the nanopores is then examined and modified by chemical cleaning or plasma cleaning if necessary, to provide an appropriate surface for epitaxial growth of the plurality of nanopillars. This is followed by epitaxial deposition of the nanorods array using an appropriate technique, including, but not limited to, e-beam deposition, sputtering, pulsed laser deposition and chemical solution deposition.

As shown in FIG. 12, the plurality of nanopillars 16 can be arranged in a regular pattern. The nanopillars 16 formed in the pores shown in FIG. 12 are arranged in a regular hexagonal arrangement. This results in an array of nanopillars 16 where each nanopillar 16 is approximately equidistant to adjacent nanopillars 16. In particular, the arrays of nanopillars 16 described herein include rows or columns of nanopillars 16 where each nanopillar 16 in the row or column is equidistant from each adjacent nanopillar 16.

As used herein, the nanopillars are equidistant if the difference between the distance between two adjacent nanopillars are within a range having a lower limit and/or an upper limit. The range can include or exclude the lower limit and/or the upper limit. The lower limit and/or upper limit can be selected from 0, 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, 3, 3.1, 3.2, 3.3, 3.4, 3.5, 3.6, 3.7, 3.8, 3.9, 4, 4.1, 4.2, 4.3, 4.4, 4.5, 4.6, 4.7, 4.8, 4.9, 5, 5.1, 5.2, 5.3, 5.4, 5.5, 5.6, 5.7, 5.8, 5.9, 6, 6.1, 6.2, 6.3, 6.4, 6.5, 6.6, 6.7, 6.8, 6.9, 7, 7.1, 7.2, 7.3, 7.4, 7.5, 7.6, 7.7, 7.8, 7.9, 8, 8.1, 8.2, 8.3, 8.4, 8.5, 8.6, 8.7, 8.8, 8.9, 9, 9.1, 9.2, 9.3, 9.4, 9.5, 9.6, 9.7, 9.8, 9.9, 10, 10.1, 10.2, 10.3, 10.4, 10.5, 10.6, 10.7, 10.8, 10.9, 11, 11.1, 11.2, 11.3, 11.4, 11.5, 11.6, 11.7, 11.8, 11.9, 12, 12.1, 12.2, 12.3, 12.4, 12.5, 12.6, 12.7, 12.8, 12.9, 13, 13.1, 13.2, 13.3, 13.4, 13.5, 13.6, 13.7, 13.8, 13.9, 14, 14.1, 14.2, 14.3, 14.4, 14.5, 14.6, 14.7, 14.8, 14.9, and 15 percent. For example, nanopillars are “equidistant” if the difference between the distance between two adjacent nanopillars is less than 15%, less than 10%, or less than 5%, or less than 1% different than the distance between other adjacent nanopillars in the row or column.

The rows or columns in these arrays include a number of nanopillars where each nanopillar in the row or column is equidistant from each adjacent nanopillar. The number of nanopillars in the rows or columns can be within a range having a lower limit and/or an upper limit. The range can include or exclude the lower limit and/or the upper limit. The lower limit and/or upper limit can be selected from 0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, and 50. For example, according to certain preferred embodiments, the number of nanopillars in the rows or columns can be at least 5 nanopillars, at least 10 nanopillars, at least 20 nanopillars, or at least 50 nanopillars.

FIG. 13 a schematic diagram illustrating growth and structure of a 3D MgO “nanofence” structure made via vapor-liquid-solid (VLS) mechanism in accordance with examples of the present invention. FIG. 13 helps to further define, further describe, and explain the formation of a nanofence in accordance with the present invention. Region I shows, as arrows, the converging of Mg and Ni from vapors to form a liquid primary Mg+Ni droplet 21 on the substrate surface 15. Region II shows, via arrows, the formation of a MgO primary nanorod 23, which can grow in a direction predominantly perpendicular (vertical) to the substrate surface 15. Region III shows, via arrows, the formation of a branched nanorod structure 29 via 3D growth of MgO secondary nanorods 25 in radially outward directions from the primary nanorod 23, which can be predominantly parallel to the substrate surface 15, initiated by secondary Mg+Ni droplets 27 forming on the side surface of the primary nanorod 23. Region IV shows the 3D formation of an integral, 3D, grid-like nanofence 31 via further growth and interactions among primary nanorods 23, secondary nanorods 25, and branched nanorod structures 29. Tertiary nanorods 33 can form on the side surfaces of secondary nanorods 25, usually in directions predominantly perpendicular to the surface 15. Quaternary and so forth nanorods can form in likewise fashion. Nanorods can grow and connect at non-perpendicular angles, but the angles can be generally predominantly perpendicular, as illustrated in the TEM images described herein. Although FIG. 13 basically shows two dimensions, the skilled artisan will recognize that growth of the structure occurs in three dimensions. The nanofence 31 is a well-developed, sturdy structure, well suited for various uses as described hereinbelow. Similar methods are described in U.S. Pat. No. 8,518,526, which is hereby incorporated by reference in its entirety.

Other preferred embodiments can provide a scalable method to form single-crystal-like, three-dimensional nanorods of metals/alloys such as copper (Cu) for battery electrodes or for solar cell collectors. Such preferred embodiments can include providing a biaxially-textured Cu foil or a biaxially-textured metal foil substrate; depositing aluminum (Al) onto the substrate, anodically oxidizing the Al layer to form a self-assembled nanostructure comprising nano-hole columns arranged in a hexagonal, self-assembled pattern. The nano-hole columns can comprise alumina (Al₂O₃). Next, according to certain preferred embodiments, copper (Cu) can be electrodeposited to form Cu nanorods. Since the Cu is electrodeposited onto a biaxially-textured surface, the Cu can grow epitaxially. The nanocolumns can be chemically etched away to leave a Cu foil having ordered, regularly placed single-crystal-like Cu nanorods.

The present invention has broad applicability for energy conversion as well as in areas of nanoelectronics such as ultra-high density magnetic storage and in nanostructured battery electrodes. Epitaxial nanorod arrays of materials with scintillation properties may be used for fabrication of advanced gamma-ray detectors.

Applications for the articles and methods described herein include dye-sensitized cells (DSC's) and hybrid organic-inorganic cells, which are widely considered as promising candidates for inexpensive, large-scale solar energy conversion. Prior art DSC's consist of a thick nanoparticle film that provides a large surface area for adsorption of light. Device efficiencies for such DSC's are limited by the trap-limited limited diffusion for electron transport, which is a slow process. It is believed that use of a nanopillar morphology would increase efficiency by accelerating electron transport and preventing recombination of electron-hole pairs.

The use of vertically-oriented, single crystal nanopillars of TiO₂, SnO or ZnO will result in significant enhancement in electron transport. Coating the aligned nanorods with an oxide such as MgO can reduce carrier recombination because the coating may serve as an additional energy barrier, as a tunneling barrier and/or a passivate recombination center. In similar prior art materials, the nanorods are not perfectly aligned, consist of polycrystalline percolation networks, or both.

The epitaxial layers described herein, e.g., nanopillars, matrix phase, coating and core phase, can be deposited by a range of deposition techniques including e-beam evaporation, sputtering, chemical and physical vapor deposition techniques, pulsed laser ablation, chemical solution processing, and electrodeposition techniques as described in U.S. Pat. No. 6,670,308, which is hereby incorporated by reference in its entirety.

Exemplary templates can be formed using a single crystal aluminum sheet (i.e., template precursor), followed by anodic oxidation to form a self-organized nanopore array in the resulting anodized aluminum oxide (AAO) layer (i.e., template). In a particular example, the template can be formed on the biaxially textured surface by depositing a layer of aluminum (Al) on the cap or top buffer layer of a single crystal-like substrate (e.g., a fully buffered RABiTS substrate with three epitaxial oxide buffers), followed by complete anodic oxidation of the aluminum layer.

Once the epitaxial nanorod array has been deposited, the Al₂O₃ template can be chemically etched away if needed and, if needed, a matrix phase deposited between the epitaxial, single-crystal-like nanopillar array. For the ultra-high density recording media application, nanopillars comprising interconnected sub-pillars of different materials such as Co and Pd, will be epitaxially deposited successively using either physical vapor deposition or electrodeposition.

Moreover, various embodiments can be broadened, for example, by using an alternative to the AAO-type template to produce a nanocatalyst pattern. Laser interference lithography can be used to quickly produce a template pattern in nanoscale and in large areas.

Moreover, it is contemplated that growth of periodic nanostructures in two directions—vertical nanopillars and transverse nanopillars—can be achieved by supplying the catalyst for growth during deposition. For example, simultaneously depositing an oxide material with a metal catalyst such as MgO+Ni growth by PLD. FIG. 13 is an image of MgO+Ni nanorods grown on a MgO single crystal. Growth of nanorods is observed vertically and horizontally due to the standard vapor-liquid-solid (VLS) growth mechanism and the MgO nanorods are epitaxial. Either of these techniques—laser interference lithography or VLS—can also be applied to existing vertically-oriented nanopillars after the template has been removed, for example to an article of FIG. 7E, 7G, 11D or 11E. This can be extended to the present invention and growth can be on large area, textured substrates.

Sub-pillars 32 can be formed using iterative variations of the methods shown in FIGS. 7 and 11. For example, the steps of FIGS. 11A-C can be performed to produce a first layer of sub-pillars 32. A second layer of sub-pillars can then be formed by introducing and anodizing another template precursor and depositing vertically-aligned, epitaxial sub-pillars 32 in the pores 42 of the second template. This process can be repeated to produce the desired number of subpillars. Following formation of the sub-pillars, coatings 28 and matrix phases 24 can be added depending on the desired application.

An alternate approach for forming sub-pillars 32 is to repeat the entire process shown in FIG. 7 or 11. Such an approach allows formation of sub-coatings 34 to match the composition of each individual sub-pillar 32 and/or formation of different matrix phases 24 to match the composition of each individual sub-pillar 32.

One embodiment provides a scalable method to form arrays of one dimensional (1D) nanorods comprising metals and/or alloys, including but not limited to Cu. The 1D nanoarrays can be useful for battery electrodes, for solar cell collectors, and for various other electronic applications. The method can be performed in a roll-to-roll configuration.

The method can also be used to produce ordered nanorods comprising an oxide, a nitride, and or a carbide. According to such embodiments, the foil with metal/alloy nanorods is subsequently oxidized, nitride or carburized to transform the metallic portions into the desired oxide, nitride or carbide.

Various embodiments provide a scalable method to form one dimensional (1D) nanorods of metals/alloys such as Cu for battery electrodes or for solar cell collectors. Preferred embodiments of such methods can include providing a Cu foil or a metal foil substrate; depositing aluminum (Al) onto the substrate, anodically oxidizing the Al layer to form a self-assembled nanostructure comprising nano-hole columns arranged in a hexagonal, self-assembled pattern. The nano-hole columns can comprise alumina (Al₂O₃). Next, according to certain preferred embodiments, copper (Cu) can be electrodeposited to form Cu nanorods. The Al₂O₃ can then be chemically etched away to leave a Cu foil having ordered, regularly placed Cu nanorods. The chemical etching can be performed using an etchant. The etchant can include one or more selected from a list of standard etchants including but not limited to copper(II) chloride, copper(II) sulfate, hydrochloric acid, nitric acid, hydrofluoric acid, potassium ferricyanide, potassium hydroxide, picric acid, and combinations thereof.

Other preferred embodiments can provide a scalable method to form single-crystal-like, 1D nanorods of metals/alloys such as Cu for battery electrodes or for solar cell collectors. Such preferred embodiments can include providing a biaxially-textured Cu foil or a biaxially-textured metal foil substrate; depositing aluminum (Al) onto the substrate, anodically oxidizing the Al layer to form a self-assembled nanostructure comprising nano-hole columns arranged in a hexagonal, self-assembled pattern. The nano-hole columns can comprise alumina (Al₂O₃). Next, according to certain preferred embodiments, copper (Cu) can be electrodeposited to form Cu nanorods. Since the Cu is electrodeposited onto a biaxially-textured surface, the Cu can grow epitaxially. The Al₂O₃ can be chemically etched away to leave a Cu foil having ordered, regularly placed single-crystal-like Cu nanorods.

Either of these preferred embodiments can be further processed to provide three dimensional (3D) nanofences comprising conductive materials. U.S. Pat. No. 8,518,526, issued Aug. 27, 2013, filed Feb. 24, 2010, claiming priority to U.S. Provisional Patent Application No. 61/231,063, and entitled Structures with Three Dimensional Nanofences Comprising Single Crystal Segments is hereby incorporated by reference in its entirety. U.S. Pat. No. 8,518,526 describes an article including a substrate having a surface, and a nanofence supported by the surface. The nanofence includes a multiplicity of primary nanorods and branch nanorods. The primary nanorods are attached to the substrate and the branch nanorods are attached to at least one other of the primary nanorods and the branch nanorods. The primary nanorods and the branch nanorods are arranged in a three-dimensional, interconnected, interpenetrating, grid-like network defining interstices within the nanofence.

The preferred embodiments described above can be further processed by depositing a thin layer of a resist on a flat portion of the substrate where there are no nanorods. The resist can be selected from a list of standard resists used in the lithographic and semiconductor industry. Resists are generally proprietary mixtures of a polymer or its precursor and other small molecules (e.g. photoacid generators) that have been specially formulated for a given lithography technology. Those of ordinary skill in the art will be able to select a suitable resist material without undue experimentation.

An aluminum (Al) layer can be deposited on top of the resist and around the surface of the nanorods. The Al layer can be anodically oxidized to form a self-assembled nanostructure comprising nano-hole columns arranged in a hexagonal, self-assembled pattern. The nano-hole columns can comprise alumina (Al₂O₃). Copper (Cu) can then be electrodeposited to form Cu nanorods. Finally, the nano-hole columns can be chemically etched to remove the Al₂O₃, leaving a Cu foil having ordered, regularly placed Cu nanofence with nanorods in two perpendicular directions—perpendicular to the Cu foil and parallel to it.

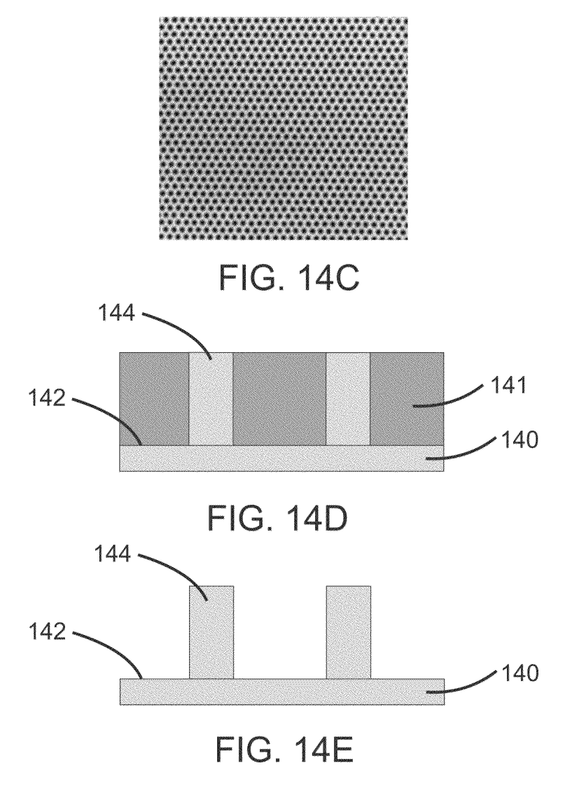

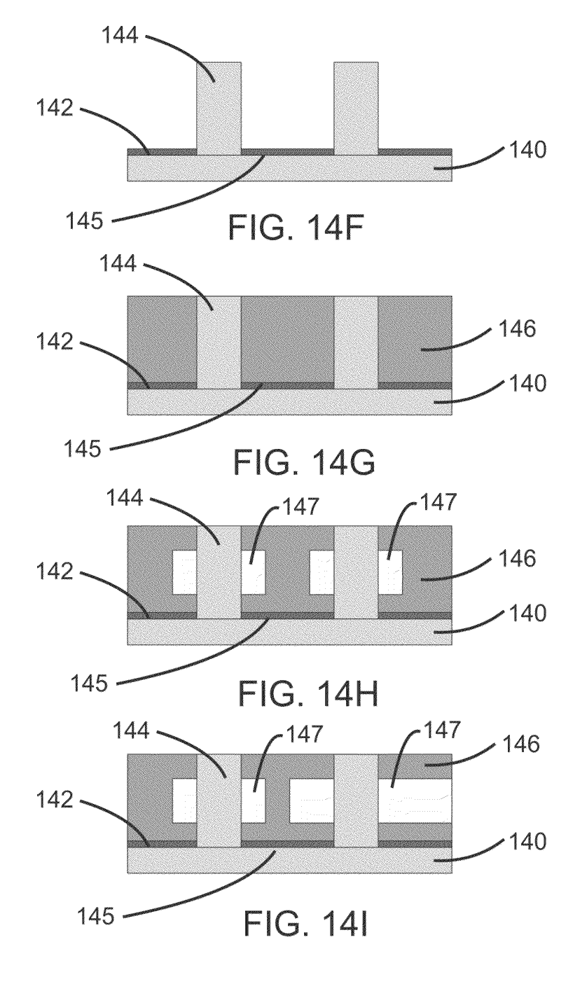

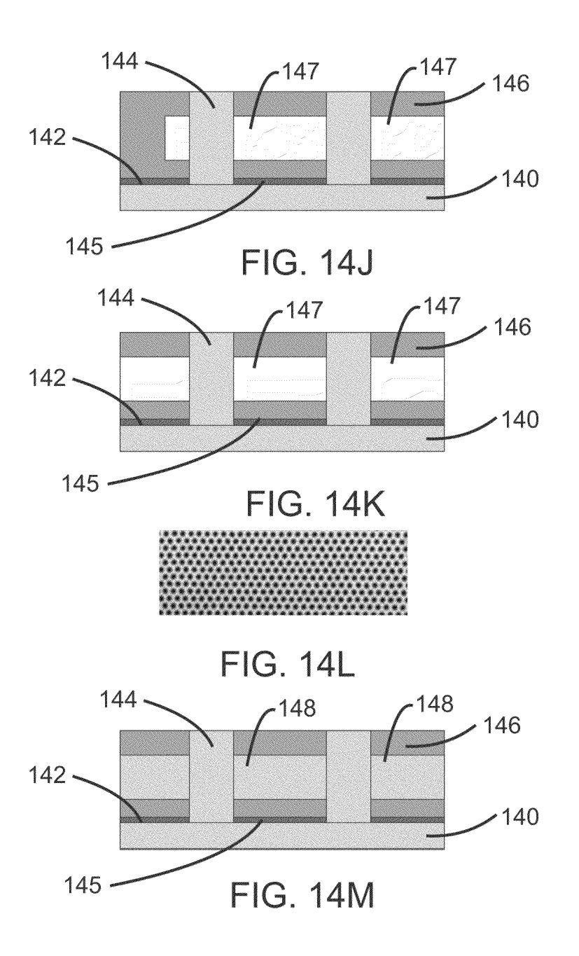

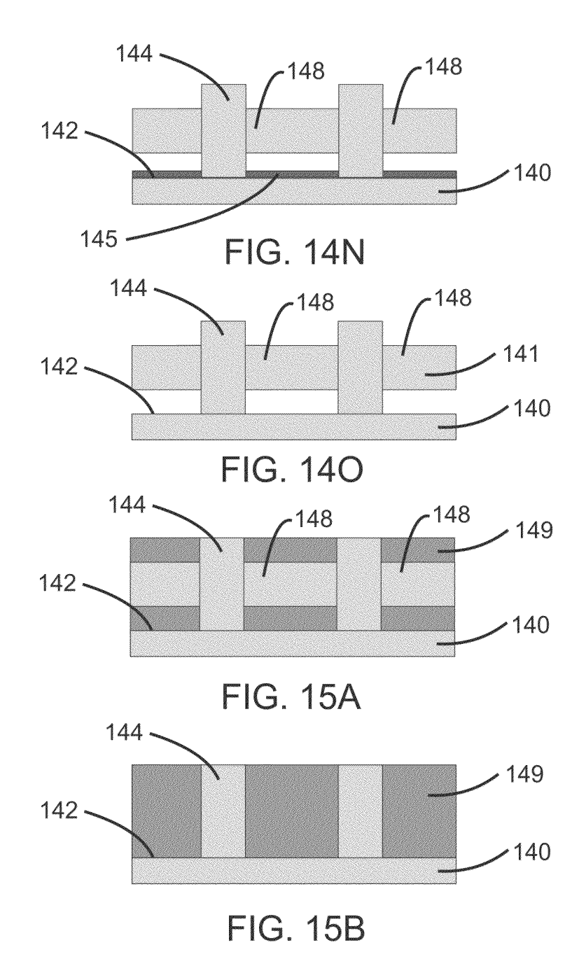

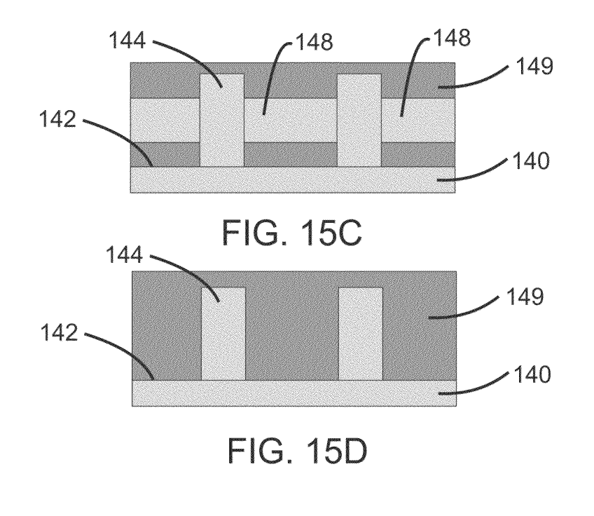

It should be noted that any of the characteristics of the above-described embodiments can be applied to the embodiments described in FIGS. 14 and 15 and vice-versa. The particular embodiments are illustrative and their features and characteristics can be interchanged by those having ordinary skill in the art.

FIGS. 14A-14E are schematic illustrations of various stages of a scalable method to form one-dimensional (1D) nanopillars. The nanopillars can be nanotubes or nanorods as described in various other embodiments. The nanopillars can include a metallic material and/or a conductive material. For example the nanopillars can include a metal and/or an alloys. A particularly preferred material, due at least in part to its good conductivity and low cost, is copper and copper alloys. The nanopillar arrays can be useful for battery electrodes or for solar cell collectors.

Referring to FIG. 14A, a layer 141 of a material can be deposited on a surface 142 of a substrate 140. The substrate can be any metallic or conductive material. One preferred metallic material is copper and alloys thereof. Particularly preferred embodiments can use a single-crystal like substrate. According to various embodiments, the substrate 140 can be a layer of copper foil. The surface 142 of the substrate 140 can be textured as described in various other embodiments. For example, the surface 142 can be biaxially-textured or cube textured. The material of layer 141 that is deposited on the surface 142 of the substrate 140 can be any material in which a plurality of nanoholes can be created through anodization. For example, the material can be a metallic material or conductive material. One particularly preferred metallic material is aluminum, which can result in an ordered array of nanohole columns when anodized.

Referring to FIG. 14B, anodizing the layer 141 can form a plurality of self-assembled nanohole columns. For example, anodizing an aluminum layer can form a self-assembled nanostructure comprised of a plurality of nano-hole columns 143 arranged in a hexagonal, self-assembled pattern.

FIG. 14C is a magnified top view of a layer 141 of aluminum after anodization, showing a plurality of nano-hole columns arranged in a hexagonal, self-assembled pattern. The nano-hole columns can be vertically-aligned.

Referring to FIG. 14D, a metallic material or a conductive material can be deposited into the nanohole columns 143 to form a plurality of nanopillars 144. For example, copper or a copper alloy can be electrodeposited to fill the nanohole columns to form a plurality of copper nanorods. As described in other embodiments, the nanopillars can be vertically-aligned, and epitaxial with respect to the surface 142 of the substrate 140.

As shown in FIG. 14E, the layer 141 can be etched away to expose the plurality of nanopillars 144, supported on the surface 142 of the substrate 140. For example, according to certain preferred embodiments, an anodized layer of aluminum (i.e. oxidized aluminum, Al₂O₃) can be chemically etched using one or more of the etchants described according to various embodiments described herein, to reveal a copper foil having ordered, regularly-placed copper nanorods.

As discussed in greater detail hereinafter with respect to FIGS. 15A-15D, the plurality of nanopillars 144 can subsequently be immersed in an electrode material to form a nanostructured anode for batteries. The electrode material can be any suitable electrode material, including but not limited to silicon.

FIGS. 14F-14O are schematic illustrations of various stages of a scalable method to form three-dimensional (3D) nanofences. For example, various embodiments provide scalable methods to form 3D nanofences of metallic materials, conductive materials, and alloys thereof, including but not limited to copper and alloys thereof. The 3D nanofences can be particularly useful for battery electrodes or for solar cell collectors.

Referring to FIG. 14F, a resist layer 145 can be deposited on the surface 142 of the substrate 140 between the nanopillars 144 that can be created according to any other embodiment described herein. In other words, a thin layer of a resist 145 can be deposited on the flat portion of the substrate 140 where there are no nanorods 144.

Referring to FIG. 14G, a layer 146 of a material can be deposited on the resist 145. The layer 146 can include any material in which a plurality of nanoholes can be created through anodization. For example, the material can be a metallic material or conductive material. One particularly preferred metallic material is aluminum, which can result in an ordered array of nanohole columns when anodized.

Referring to FIGS. 14H, 14I, 14J, and 14K, anodizing the layer 146 can form a plurality of self-assembled nanohole columns. For example, anodizing an aluminum layer can form a self-assembled nanostructure comprised of a plurality of nano-hole columns 143 arranged in a hexagonal, self-assembled pattern. The plurality of nanohole columns can have a longitudinal axis that is substantially horizontally-aligned or parallel with the surface 142 of the substrate 140. The plurality of nanohole columns can extend only partly away from the nanopillars 144 as shown in FIGS. 14G and 14H or the plurality of nanohole columns can extend to an extremity of the layer 146 as shown in FIGS. 14I, 14J, and 14K. In other words, it is possible to anodically oxidize an aluminum layer to form a self-assembled nanostructure comprised of nano-hole columns arranged in a hexagonal, self-assembled pattern. It should be noted that although only one horizontal nanohole column is illustrated in FIG. 14K, for example, a plurality of nanohole columns can be formed. As shown in FIG. 14L, which is a side view of the layer 146, a plurality of horizontally-aligned nanohole columns can be formed in layer 146. FIG. 14L also demonstrates the hexagonal, self-assembled pattern already discussed.

Referring to FIG. 14M, a metallic material or a conductive material can be deposited into the nanohole columns 147 to form a plurality of horizontal nanopillars 148 also referred to as nanobranches. For example, copper or a copper alloy can be electrodeposited to fill the nanohole columns to form a plurality of copper nanorods. As described in other embodiments, the nanopillars can be horizontally-aligned and epitaxial. The nanobranches or horizontal nanopillars 148 can be epitaxial with respect to the nanopillars upon which they are supported, for example.

As shown in FIG. 14N, the layer 146 can be etched away to reexpose the plurality of vertical nanopillars 144, supported on the surface 142 of the substrate 140 and to expose the plurality of horizontal nanopillars 148 supported on the vertical nanopillars 144. For example, according to certain preferred embodiments, an anodized layer of aluminum (i.e. oxidized aluminum, Al₂O₃) can be chemically etched using one or more of the etchants described according to various embodiments described herein, to reveal a copper foil having copper nanofence disposed thereon. As shown in FIG. 14O, the etching step can also remove the resist 145. In other words, according to various embodiments, a copper foil having an ordered, regularly placed coppered nanofence with nanorods in two perpendicular directions—perpendicular to the copper foil and parallel to it—can be produced.

Referring to FIGS. 15A-15D the plurality of vertical nanopillars 144 or nanofence combinations of the vertical nanopillars 144 and the horizontal nanopillars 148 can subsequently be immersed in an electrode material 149 to form a nanostructured anode for batteries. The electrode material can be any suitable electrode material, including but not limited to silicon. The electrode material 149 can be coextensive with an extent of the vertical nanopillars 144 and/or the horizontal nanopillars 148, as shown in FIGS. 15A and 15B, or can completely immerse the vertical nanopillars 144 and/or the horizontal nanopillars 148, as shown in FIGS. 15C and 15D. For example, an electrode material 149, such as silicon can be deposited around the conducting nanopillars or nanofence to form a nanostructured silicon anode, which can be useful for a variety of purposes, including but not limited to batteries.

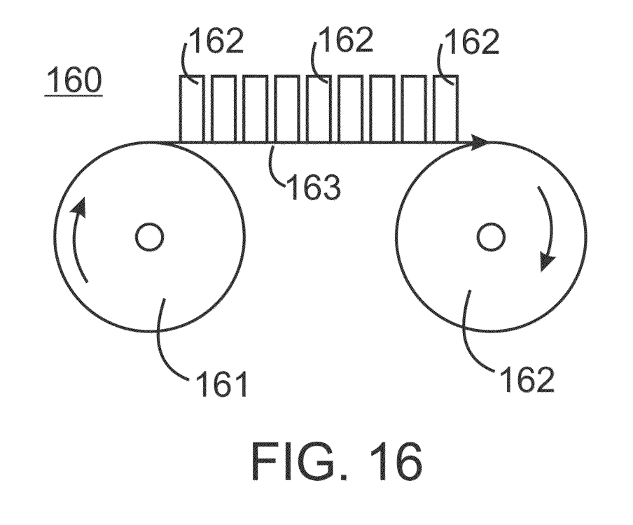

Referring to FIG. 16, a schematic illustration of “reel-to-reel” configuration 160 is shown. A flexible substrate 163 can be coiled around a first reel 161. The flexible substrate can include a metallic material and/or a conductive material as described herein. The flexible substrate can be a foil or a thin-film. For example, according to various particularly preferred embodiments the flexible substrate can be copper foil or a foil comprising copper or a copper alloy. The flexible substrate 163 can be uncoiled from the first reel 161 and moved toward a second reel 162, about which the flexible substrate 163 can be coiled or wound. One or more processing units 162 can interact with the flexible substrate 162 as it is passed from the first reel 161 to the second reel 162. The one or more processing units 162 can perform the steps of any of the methods described herein. For example, the one or more processing units 162 can include structure and apparatus for depositing a first layer on a surface of a substrate, wherein the substrate comprises a first metallic material, wherein the first layer comprises a second metallic material; anodically oxidizing the first layer to form a first self-assembled nanostructure defining a first plurality of nano-hole columns; filling the first plurality of nano-hole columns with a third metallic material to form a first plurality of nanopillars; removing the first self-assembled nanohole structure to leave the first plurality of nanopillars supported on the surface of the substrate; depositing a resist layer on the substrate at interstices between the first plurality of nanopillars; depositing a second layer comprising a fourth metallic material on the resist and the first plurality of nanopillars; anodically oxidizing the second layer to form a second self-assembled nanostructure comprised of a second plurality of nano-hole columns, wherein the second plurality of nano-hole columns are perpendicular to the first plurality of nanopillars; filling the second plurality of nano-hole columns with a fifth metallic material to form a second plurality of nanopillars; and removing the second self-assembled nanostructure to leave the second plurality of nanopillars supported by the first plurality of nanopillars.

The various embodiments described herein, can be extended to alloy nanorods and the metal substrate can be an alloy or anything conducting. The method can be done in a high-speed, reel-to-reel configuration. The method can also result in ordered, oxide or nitride or carbide nanorods, for example, if the foil with metal/alloy nanorods is subsequently oxidized, nitride or carburized. According to various embodiments, having a biaxially-textured, single-crystal-like metallic (e.g. copper) foil, makes the metallic (e.g. aluminum) layer aligned or epitaxial. The nanohole columns formed in the aluminum layer are all aligned then too. The metal nanorods formed upon filing of holes are also fully aligned and can grow epitaxially on the single-crystal-like substrate.

Although the present invention has been described in considerable detail with reference to certain preferred versions thereof, other versions are possible. Therefore, the spirit and scope of the appended claims should not be limited to the description of the preferred versions contained herein. The articles described herein can be formed using a variety of different methods consistent with the descriptions provided herein. However, it is to be understood that the methods described herein are exemplary and that there may exist variations that would also produce the articles disclosed herein.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means for” performing a specified function, or “step for” performing a specific function, is not to be interpreted as a “means” or “step” clause as specified in 35 U.S.C §112, sixth paragraph. In particular, the use of “step of” in the claims herein is not intended to invoke the provisions of 35 U.S.C §112, sixth paragraph.

What is claimed is:

1. A battery electrode comprising:
a substrate comprising a first conductive material; and
a plurality of nanopillars comprising a second conductive material, wherein the plurality of nanopillars are vertically-aligned, and wherein the plurality of nanopillars are disposed on a surface of the substrate.

2. The battery electrode according to claim 1, wherein the first conductive material is selected from the group consisting of copper, nickel, aluminum, iron, silver and their alloys thereof, and combinations thereof.

3. The battery electrode of claim 1, wherein the plurality of nanopillars are epitaxial.

4. The battery electrode according to claim 1, wherein the second conductive material is selected from the group consisting of copper, nickel, aluminum, iron, silver and their alloys thereof, and combinations thereof.

5. The battery electrode according to claim 1, wherein the surface of the substrate is single-crystal-like.

6. The battery electrode according to claim 1, wherein the surface of the substrate is biaxially-textured.

7. The battery electrode according to claim 1, wherein the substrate is flexible.

8. The battery electrode according to claim 7, wherein the electrode is fabricated in a reel-to-reel configuration.

9. The battery electrode according to claim 1, wherein the surface of the substrate is {100}<100>.

10. The battery electrode according to claim 1, wherein one or more of the plurality of nanopillars are biaxially textured.

11. The battery electrode according to claim 1, wherein one or more of the plurality of nanopillars are {100}<100>.

12. The battery electrode according to claim 1, wherein the plurality of nanopillars have regular nanoscale spacings.

13. The battery electrode according to claim 1, wherein one or more of the plurality of nanopillars have a diameter in the range of 1-200 nm.

14. The battery electrode according to claim 1, further comprising a plurality of nanobranches supported by the nanopillars,
wherein the plurality of nanobranches are horizontally-aligned,
wherein the plurality of nanobranches are epitaxial,
wherein the plurality of nanobranches comprise a third conductive material.

15. The battery electrode according to claim 1, wherein the third conductive material is selected from the group consisting of copper, nickel, aluminum, iron, silver and their alloys thereof, and combinations thereof.

16. The battery electrode according to claim 15, wherein one or more of the plurality of nanobranches have a diameter in the range of 1-200 nm.

17. The battery electrode according to claim 15, wherein one or more of the plurality of nanobranches are single-crystal-like.

18. The battery electrode according to claim 15, wherein one or more of the plurality of nanobranches are cube-textured.

19. The battery electrode according to claim 15, wherein one or more of the plurality of nanobranches are self-assembled with regular nanoscale spacings.

20. A method of making a battery electrode comprising:
depositing a first layer on a surface of a substrate, wherein the substrate comprises a first metallic material, wherein the first layer comprises a second metallic material;
anodically oxidizing the first layer to form a first self-assembled nanostructure defining a first plurality of nano-hole columns;
filling the first plurality of nano-hole columns with a third metallic material to form a first plurality of nanopillars;
removing the first self-assembled nanohole structure to leave the first plurality of nanopillars supported on the surface of the substrate.

21. The method according to claim 20, wherein the first metallic material is copper or an alloy thereof.

22. The method according to claim 20, wherein the surface of the substrate is single-crystal-like.

23. The method according to claim 20, wherein the surface of the substrate is biaxially-textured.

24. The method according to claim 20, wherein the second metallic material is a metal that upon anodization forms an ordered array of nanohole columns through the first layer.

25. The method according to claim 20, wherein the second metallic material is selected from the group consisting of aluminum and titanium.

26. The method according to claim 20, wherein the third metallic material is copper or an alloy thereof.

27. The method according to claim 20, wherein the third metallic material is single-crystal-like.

28. The method according to claim 20, wherein the first plurality of nano-hole columns are arranged in a hexagonal, self-assembled pattern.

29. The method according to claim 20, wherein the first plurality of nano-hole columns comprise alumina.

30. The method according to claim 20, wherein the third metallic material is electrodeposited to fill the first plurality of hollow nanopillars.

31. The method according to claim 20, wherein the first plurality of nanopillars are vertically-aligned with respect to the surface of the substrate.

32. The method according to claim 20, wherein the first plurality of nanopillars are epitaxial with respect to the surface of the substrate.

33. The method according to claim 20, wherein removing the first self-assembled nanostructure comprises one selected from the group consisting of chemical etching, plasma etching, reverse sputtering, ion-bombardment, and combinations thereof.

34. The method according to claim 20, wherein the surface of the substrate is cube-textured.

35. The method according to claim 20, wherein each of the first plurality of nano-hole columns have a length of from 1 nm to 1 mm and a diameter of 1 nm to 100 nm.

36. The method according to claim 20, further comprising immersing the first plurality of nanopillars in an electrode material.

37. The method according to claim 36, wherein the electrode material is silicon.

38. The method according to claim 20, wherein the substrate is flexible and the method is performed in a reel-to-reel configuration.

39. The method according to claim 20, further comprising:
depositing a resist layer on the substrate at interstices between the first plurality of nanopillars;
depositing a second layer comprising a fourth metallic material on the resist and the first plurality of nanopillars;
anodically oxidizing the second layer to form a second self-assembled nanostructure comprised of a second plurality of nano-hole columns,
wherein the second plurality of nano-hole columns are perpendicular to the first plurality of nanopillars;
filling the second plurality of nano-hole columns with a fifth metallic material to form a second plurality of nanopillars; and
removing the second self-assembled nanostructure to leave the second plurality of nanopillars supported by the first plurality of nanopillars.

40. The method according to claim 39, wherein the fourth metallic material is aluminum.

41. The method according to claim 39, wherein the fifth metallic material is copper or an alloy thereof.

42. The method according to claim 39, wherein the second self-assembled nanostructure comprises alumina.

43. The method according to claim 39, wherein the second plurality nano-hole columns are arranged in a hexagonal, self-assembled pattern.

44. The method according to claim 39, wherein the fifth metallic material is electrodeposited to fill the second plurality of hollow nanopillars.

45. The method according to claim 39, wherein the second plurality of nanopillars are horizontally-aligned with respect to the surface of the substrate.

46. The method according to claim 39, wherein the second plurality of nanopillars are epitaxial.

47. The method according to claim 39, wherein removing the second self-assembled nanostructure comprises one selected from the group consisting of chemical etching, plasma etching, reverse sputtering, ion-bombardment, and combinations thereof.

48. The method according to claim 39, wherein the second plurality of nanopillars interconnect with the first plurality of nanopillars to form a nanofence.

49. The method according to claim 39, wherein the resist layer has a thickness of from a 1 nm to 100 nm.

50. The method according to claim 39, further comprising immersing the first plurality of nanopillars in an electrode material.

51. The method according to claim 39, wherein the electrode material is silicon.

52. The method according to claim 39, wherein the substrate is flexible and the method is performed in a reel-to-reel configuration.
